(19) United States
(12) Patent Application Publication
(10) Pub. No.: US 2009/0245981 A1
(43) Pub. Date: Oct. 1, 2009

(54) CLOSED CONTAINER, LID OPENING AND CLOSING SYSTEM FOR CLOSED CONTAINER, WAFER TRANSFER SYSTEM, AND LID CLOSING METHOD FOR CLOSED CONTAINER

(75) Inventors: Toshihiko Miyajima, Tokyo (JP); Mutsuo Sasaki, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/411,767

(22) Filed: Mar. 26, 2009

(30) Foreign Application Priority Data
Mar. 27, 2008 (JP) 2008-082938

(51) Int. Cl. H01L 21/673; B65D 45/16; B65D 51/00; B23P 19/04

(52) U.S. Cl. 414/222.02; 220/324; 220/377; 29/700

(57) ABSTRACT

A plurality of detection marks that can be detected from outside are provided on a lid of a pod. Whether the lid is appropriately fixed on the pod main body is determined by detecting the presence of the marks at predetermined positions. Thus, whether the lid is appropriately fixed on the pod is detected in the operation of closing the pod opening with the lid in a FIMS system.

This application claims priority from Japanese Patent Application No. 2008-082938 filed on Mar. 27, 2008, which is hereby incorporated by reference herein.

### BACKGROUND OF THE INVENTION

1. Field of the Invention

The present invention relates to what is called a FIMS (Front-Opening Interface Mechanical Standard) system that is used to transport wafers stored in the interior of a transfer container called a pod between semiconductor processing apparatuses in a semiconductor manufacturing process etc. More specifically, the present invention relates to a pod called a FOUP (Front-Opening Unified Pod) or a closed container for storing wafers and a lid opening and closing system that fixedly attaches a lid to such a pod from which the lid has been detached to close the pod opening in a FIMS system for opening and closing the lid of the pod to allow transfer of wafers into/out of the pod. The present invention also relates to a wafer transfer system including such a pod and a lid opening and closing system. The present invention further relates to a lid closing method for closing such a pod with a lid.

2. Description of the Related Art

Previously, the semiconductor manufacturing process had been performed in what is called a clean room that is constructed by establishing a high degree of cleanliness in the room in which semiconductor wafers are handled. In recent years, however, in view of an increase in the wafer size and with a view to reduce cost incurred in maintenance of the clean room, use has been made of a method of keeping clean only the interior of a processing apparatus, a pod (i.e. a container for storing wafers) and a mini environment through which substrates or wafers are transferred between the pod and the processing apparatus.

The pod is composed of a substantially cubical main body having shelves provided therein that can hold a plurality of wafers in a parallel and separated state and an opening provided on one of the sides or external walls thereof through which wafers can be transferred into/out of it, and a lid for closing the opening. Those pods which have an opening provided not on the bottom but on one lateral side thereof (i.e. the side to be directly opposed to the mini environment) are collectively called FOUPs (Front-Opening Unified Pods). The present invention mainly pertains to technologies that use the FOUP.

A structure that defines the above mentioned mini environment has a opening portion to be opposed to the opening of the pod, a door that closes the opening portion, another opening portion or the processing apparatus side opening portion provided on the semiconductor processing apparatus side of the structure, and a transferring robot that is adapted to reach into the interior of the pod through the opening portion to pick up a wafer and transfer it into the processing apparatus through the opening portion on the processing apparatus side. The structure that defines the mini environment further has a support table that supports the pod in such a way that the pod opening is disposed just in front of the door.

On the top surface of the support table are provided positioning pins to be fitted into positioning holes provided on the bottom surface of the pod to regulate the placement position of the pod and a clamp unit for engaging with a clamped portion provided on the bottom surface of the pod to fix the pod to the support table. Typically, the support table is adapted to be movable toward and away from the door over a predetermined distance. When the wafers in a pod are to be transferred into the processing apparatus, the pod placed on the support table is moved until the lid of the pod abuts the door, and then after the abutment, the lid is detached from the opening of the pod by the door (see Japanese Patent Application Laid-Open No. 11-288991). By these operations, the interior of the pod and the interior of the processing apparatus are bought into communication with each other through the mini environment. Thereafter, the wafer transferring operation is performed repeatedly. All of the support table, the door, the opening portions, a mechanism for opening and closing the door, walls partly defining the mini environment and having the openings and other components collectively constitute what is called a FIMS system.

As described in detail in Japanese Patent Application Laid-Open No. 2001-077177, the lid of a conventional pod is provided with tongues that are extendable/retractable outwardly beyond/into the outer periphery of the lid. The pod body and the lid are brought into an engaging state and a disengaged state by extension and retraction of the tongues. When, for example, the pod opening is closed by the lid, the tongues provided on the lid may sometimes fail to be inserted precisely into receiving holes on the pod due to the presence of a foreign matter(s) between the opening and the lid or a positional displacement resulting from accumulation of errors such as a positional error of the pod on the support table and an operation error of the door etc. In such cases, if it is mistakenly determined that the pod opening is completely closed by the lid, subsequent operations such as transportation of the pod will be performed, and there is a possibility that the lid is dislocated or detached from the pod, for example, during transportation of the pod. A countermeasure to the above described situation that has been under development currently is to provide a sensor that detects the operation of a motor that drives the tongues to estimate the operational position of the tongues, thereby determining whether or not the opening is closed successfully, as disclosed in Japanese Patent Application Laid-Open No. 2001-077177.

In pods having a conventional size, there is not much possibility of occurrence of a failure in closing by the lid by virtue of the relationship among the sizes of the lid, the receiving hole on the pod and the projecting portion of the tongue. In addition, the operation of the tongue can be detected relatively easily, and it is possible to determine whether the closing is successful or not by detecting abnormality in a mechanism that operates the tongue. However, an increase in the size of the pod with an in crease in the wafer diameter in recent years necessitated a decrease in the size of the engagement portion relative to the size of the pod. For this reason, it is considered that the possibility of occurrence of a failure in closing will increase, or there will be cases where an operation error of the tongue cannot be detected even when a failure in closing occurs.

### SUMMARY OF THE INVENTION

The present invention has been made in view of the above describe situation and has as an object to provide a lid opening and closing system that can detect whether steady engagement of the lid with the pod is achieved by a latch tongue in the operation of attaching the lid to the pod and enables removal of the pod from the FIMS after the detection, a closed container for use with such a lid opening and closing system, a wafer transfer system including such a lid opening and closing system and such a closed container, and a method of closing such a closed container with a lid.

To achieve the above object, according to the present invention, there is provided a closed container comprising a lid having a flat plate-like shape; and a main body having an opening to be closed by the lid on one lateral side thereof in which an object to be stored can be stored, wherein the lid has a latch mechanism including a latch tongue that is caused to project from the flat plate-like shape by an operation from outside and a detection mark that is disposed at an end portion of the latch tongue and can reflect a sensor light of a specific sensor that detects presence/absence of an object by projecting and receiving the sensor light, and the main body has a tongue receiving hole in which the latch tongue projecting from the flat plate-like shape of the lid can be received so that fixation of the lid and the main body is achieved by engagement of the latch tongue with the tongue receiving hole in a biased state, and a detection window disposed at a position that allows the specific sensor to project the sensor light to the detection mark and to receive the sensor light from the detection mark in a state in which the latch tongue is engaging with the tongue receiving hole while biased.

In the above described closed container, it is preferred that an open portion of the detection window be stopped by a transparent closing member. It is also preferred that the detection window be provided on the main body along a direction perpendicular to a direction in which the latch tongue extends.

To achieve the above object, according to the present invention, there is provided a lid opening and closing system that opens and closes the lid of the above described closed container to allow transfer of the object to be stored into/out of the interior of the closed container, comprising: a mini environment having an opening portion; a door that can move between a position at which it closes the opening portion and a position at which it leaves the opening portion open and has lid holding means for holding the lid and a latch key that can operate the latch mechanism; a docking plate on which the closed container can be placed in such a way that the opening is opposed to the opening portion and that can move toward and away from the opening portion with the closed container thereby disposing, when located at a position close to the opening portion, the closed container at a position at which the lid is to be detached and transfer of the object to be stored into/out of it is to be performed, and disposing, when located at a position away from the opening portion, the closed container at a position at which loading and unloading of the closed container is to be performed; docking plate driving means for causing the docking plate to move toward and away from the opening portion; and the specific sensor that can detect presence of the detection mark in the tongue receiving hole by projecting the sensor light into the interior of the tongue receiving hole and receiving the sensor light from the interior of the tongue receiving hole through the detection window.

To achieve the above object, according to the present invention, there is provided a wafer transfer system comprising the above described closed container and the above described lid opening and closing system that opens and closes the lid of the closed container to allow transfer of the object to be stored into/out of the interior of the closed container, wherein the object to be stored is a wafer.

To achieve the above object, according to the present invention there is provided a closed container comprising: a lid having a flat plate-like shape; and a main body having an opening to be closed by the lid on one lateral side thereof in which an object to be stored can be stored, wherein the lid has a latch mechanism including a latch tongue that is caused to project from the flat plate-like shape in a direction in which it extends and biased to shift in a direction different from the direction in which it extends by an operation from outside and a detection mark that can be detected in terms of presence/absence thereof by a specific sensor, the main body has a tongue receiving hole in which the latch tongue projecting from the flat plate-like shape of the lid can be received and a detection window that allows the specific sensor to detect the presence of the detection mark at a predetermined position in a state in which the lid is fixed to the main body by the insertion of the latch tongue into the tongue receiving hole and the shit of the latch tongue, and the specific sensor is a sensor using light, and the detection mark comprises a member that reflects light.

In this closed container, it is preferred that the detection mark be provided on the latch tongue.

To achieve the above object, according to the present invention, there is provided a lid closing method, which is applied to a lid opening and closing system that opens and closes a lid of a closed container including the lid having a flat plate-like shape and a main body having an opening to be closed by the lid on one lateral side thereof in which an object to be stored can be stored to allow transfer of the object to be stored into/out of the interior of the closed container, for closing the opening by the lid, the lid having a latch mechanism including a latch tongue that is caused to project from the flat plate-like shape by an operation from outside and a detection mark that is disposed at an end portion of the latch tongue and can reflect a sensor light of a specific sensor that detects presence/absence of an object by projecting and receiving the sensor light, the main body having a tongue receiving hole in which the latch tongue projecting from the flat plate-like shape of the lid can be received so that fixation of the lid and the main body is achieved by engagement of the latch tongue with the tongue receiving hole in a biased state, and a detection window disposed at a position that allows the specific sensor to project the sensor light to the detection mark and to receive the sensor light from the detection mark in a state in which the latch tongue is engaging with the tongue receiving hole while biased, and the lid opening and closing system having a mini environment having an opening portion, a door that can move between a position at which it closes the opening portion and a position at which it leaves the opening portion open and has lid holding means for holding the lid and a latch key that can operate the latch mechanism, a docking plate on which the closed container can be placed in such a way that the opening is opposed to the opening portion and that can move toward and away from the opening portion with the closed container thereby disposing, when located at a position close to the opening portion, the closed container at a position at which the lid is to be detached and transfer of the object to be stored into/out of it is to be performed, and disposing, when located at a position away from the opening portion, the closed container at a position at which loading and unloading of the closed container is to be performed, docking plate driving means for causing the docking plate to move toward and away from the opening portion, and the specific sensor that can detect presence of the detection mark in the tongue receiving hole by projecting the sensor light into the interior of the tongue receiving hole and receiving the sensor light from the interior of the tongue receiving hole through the detection window, the method comprising the steps of: setting the lid at a position at which it closes the opening by operating the door; inserting the latch tongue into the tongue receiving hole by operating the latch mechanism by the latch key so that the lid will be fixed on the closed container; detecting the presence of the detection mark at a predetermined position, by the specific sensor; causing the docking plate driving means to operate in such a way as to displace the docking plate from the position close to the opening portion while maintaining holding of the lid by the door; detecting displacement of the docking plate and displacement of the detection mark from the predetermined position caused by the operation of the docking plate driving means; and determining whether or not the state of fixation of the lid and the closed container is appropriate based on a result of detection of displacement of the docking plate and a result of detection of displacement of the detection mark.

According to the present invention, whether or not a tongue of the lid engages with the main body of a pod can be detected with reliability irrespective of the size of the pod. Therefore, for example, the possibility of dislocation of the lid during pod transportation can be eliminated, and the pod transportation speed can be increased. Thus, the variety of options in the operation condition of the pod transportation system or the variety of options in the transportation system itself can be increased.

The above and other objects, features, and advantages of the invention will become more apparent from the following detailed description taken in conjunction with the accompanying drawings.

### BRIEF DESCRIPTION OF THE DRAWINGS

FIG. 1 is a perspective view of showing the general structure of a typical pod.

FIG. 2A is a diagram showing a latch mechanism of the pod shown in FIG. 1.

FIG. 2B is a diagram showing the latch mechanism of the pod shown in FIG. 1.

FIG. 3 is a cross sectional view showing the general structure of the pod shown in FIG. 1.

FIG. 4 is a cross sectional view showing, in a manner similar to FIG. 3, the general structure of a pod according to an embodiment of the present invention.

FIG. 5 is a cross sectional view showing, in a manner similar to FIG. 3, the general structure of a pod according to another embodiment of the present invention.

FIG. 6 is an enlarged view showing a latch tongue and its vicinity of the pod according to the embodiment shown in FIG. 5.

FIG. 7 is an enlarged view showing, in a manner similar to FIG. 6, a latch tongue and its vicinity of a pod according to another embodiment of the present invention.

FIG. 8 is an enlarged view showing, in a manner similar to FIG. 6, a latch tongue and its vicinity of a pod according to still another embodiment of the present invention.

FIG. 9 is an enlarged view showing, in a manner similar to FIG. 6, a latch tongue and its vicinity of a pod according to still another embodiment of the present invention.

FIG. 10 is a side cross sectional view showing a load port apparatus according to an embodiment of the present invention.

FIG. 11 is an enlarged cross sectional view showing, in a manner similar to FIG. 10, the general structure of the relevant portion of the load port apparatus according to the embodiment of the present invention.

FIG. 12A is an enlarged schematic view showing a door and a structure around a first opening portion of the load port apparatus shown in FIG. 10.

FIG. 12B schematically shows the structure shown in FIG. 12A as seen from the direction indicated by arrow 12B.

FIG. 13 is a block diagram showing the general configuration of the FIMS system according to an embodiment of the present invention.

FIG. 14 is a flow chart of a process for closing a lid of a pod or a closed container according to an embodiment of the present invention.

FIG. 15A is a side view showing the state of the pod main body and the lid at a certain step in the process of the flow chart of FIG. 14.

FIG. 15B is a side view showing the state of the pod main body and the lid at a certain step in the process of the flow chart of FIG. 14.

FIG. 15C is a side view showing the state of the pod main body and the lid at a certain step in the process of the flow chart of FIG. 14.

FIG. 15D is a side view showing the state of the pod main body and the lid at a certain step in the process of the flow chart of FIG. 14.

FIG. 15E is a side view showing the state of the pod main body and the lid at a certain step in the process of the flow chart of FIG. 14.

FIG. 15F is a top view showing the state of the pod main body and the lid at the step shown in FIG. 15D.

### DESCRIPTION OF THE EMBODIMENTS

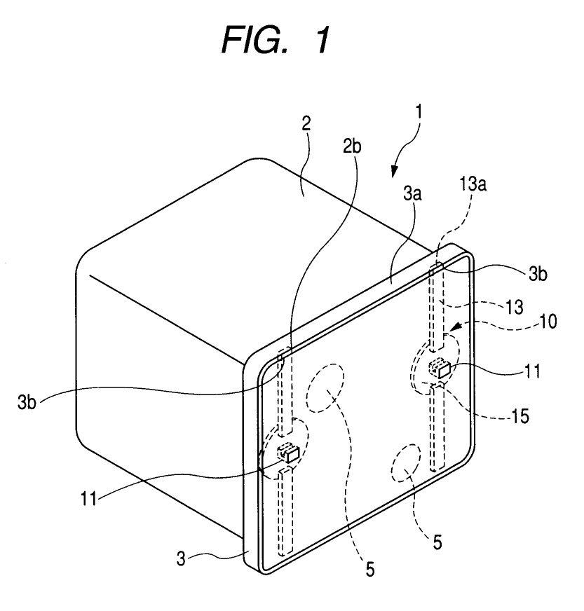

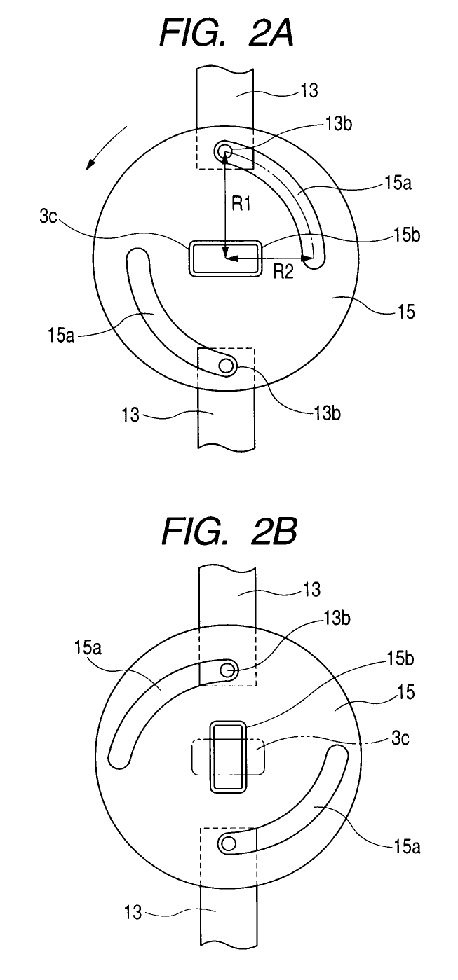

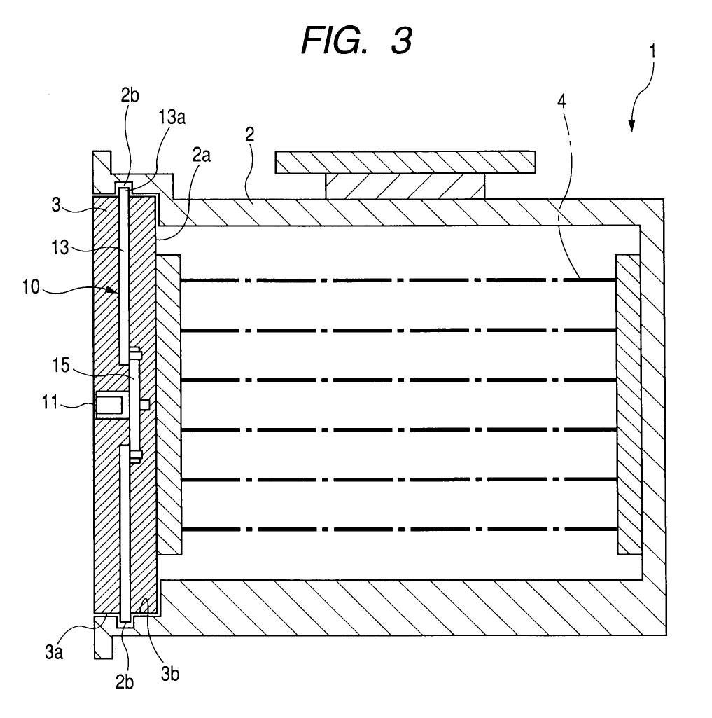

Before describing an embodiment of the present invention, a conventional latch mechanism of a pod or a closed container will be briefly described with reference to FIGS. 1, 2A, 2B, and 3. FIG. 1 is a schematic perspective view of a pod 1, where components that are not visible from outside are also illustrated by broken lines. FIGS. 2A and 2B are enlarged front views of the latch mechanism, showing a latched state and an unlatched state respectively. FIG. 3 is a schematic cross sectional view of the pod with a lid fixed thereon. The pod 1 is composed of a substantially cubical main body 2 and the lid 3. A plurality of objects 4 to be stored such as wafers can be stored in the interior of the pod body in such a way that they are arranged in parallel one above another along the vertical direction. The main body 2 has an opening 2a that can be closed by the lid 3 on one lateral side thereof. The lid 3 has a flat plate-like shape. (Strictly speaking, the lid 3 has a projection(s), recess(es), sealing member and latch keys that will be described later. Therefore, the lid 3 is defined herein as a member having a substantially plate-like shape.) On the outer side surface (the surface to be opposed to the lid opening and closing apparatus) are provided suction regions 5 and receiving holes 11 that are in communication with rectangular holes 3c of latch mechanisms 10. The latch mechanisms 10 are accommodated in the interior of the flat plate-like lid 3, and the receiving holes 11 are disposed in such a way that they are aligned and in communication with the rectangular holes 3c when the rectangular holes 3c are located at specific positions. The suction regions 5 are adapted to be sucked by suction pads (which will be described later) provided in the lid opening and closing apparatus. The surface of the suction regions is made smooth so that the lid can be held by suction by the suction pad easily and reliably.

The lid 3 is provided with two latch mechanisms 10, each of which is composed of a latch bar 13 and a disk 15. These components are provided in the interior of the lid 3. The latch bar 13 is a plate-like member extending in one direction and has a portion that functions as a latch tongue 13a at one end (front end) thereof and a connection pin 13b at the other end (rear end). The connection pin 13b stands perpendicularly from the extending surface of the latch bar 13. The latch tongue 13a has a width and a thickness that allow it to project from a projection hole 3b provided on the outer peripheral surface 3a of the lid 3. In other words, the latch tongue 13a may be considered as a component that can project out of the substantially flat plate-like lid. The latch bar 13 is provided for each projection hole 3b. On each of the upper and lower sides of the peripheral surface 3a of the lid 3 are two projection holes 3b. The projection holes 3b on the opposed sides are parallel and opposed to each other. Two latch bars 13 associated with opposed projection holes 3b are aligned with each other along the direction in which they extend so that they can project from the projection holes by sliding along the axial direction.

The disk 15 is disposed in such a way that its center is located at the center of the gap between the latch bars 13 that are aligned along the longitudinal direction. The disk 15 is supported in such a way as to be rotatable relative to the lid 3. The disk 15 has cam grooves 15a disposed symmetrically with respect to the rotation center and a rectangular key receiving hole 15b elongated in one direction. The center of the rectangular key receiving hole 15b coincides with the center of the disk 15. Each cam groove 15a extends over a range that forms an angle of 90 degrees with respect to the center of the disk 15, and the distance R1 between the center of the width of the groove at one end thereof and the center of the disk is different from the distance R2 between the center of the width of the groove at the other end thereof and the center of the disk. The connection pin 13b mentioned above is inserted through the cam groove 15a. With the above configuration, when the disk 15 is rotated by a latch key (which will be described later) inserted in the key receiving hole 15b, the distance between the connection pin 13b and the center of the disk changes along the cam groove 15a, which causes the latch bar 13 to slide or move along the longitudinal direction. By designing the length of the latch bar 13 appropriately, the state in which the latch tongue 13a projects beyond the outer periphery of the lid 3a and the state in which it is received in the lid 3a are achieved, namely the states of the disk 15 shown in FIG. 3A (in which the latch bar 13 is extended) and in FIG. 3B (in which the latch bar 13 is retracted) respectively are achieved.

In connection with the latch mechanism 10 accommodated in the interior of the lid 3, a rectangular hole 3c is provided on the outer surface of the lid 3 in such a way that it is aligned with the key receiving hole 15b in the state shown in FIG. 3A. As will be described later, the latch key has a T-shape with an enlarged diameter portion having a thickness substantially equal to or smaller than the depth of the key receiving hole 15b. Therefore, when the latch key is fully received in the rectangular hole 3c, the outer wall of the lid does not hinder the rotation of the latch key and the disk 15 at all. By operating the latch mechanisms having the above described structure, the latch tongues 13a can be projected into/retracted from tongue receiving holes 2b provided on the pod main body 2, whereby fixation/detachment of the lid 3 to/from the pod main body 2 can be achieved.

Actual fixation of the lid 3 to the pod main body 2 is not achieved only by inserting the latch tongue 13a into the interior space of the tongue receiving hole 2b. Therefore, to fix the lid 3 to the pod main body 2, it is preferred that the latch tongue 13a comes into contact with the inner surface of the tongue receiving hole 2b to achieve engaging state. For this purpose, it is preferred, for example, that a tapered surface be provided at the end of the latch tongue 13a so that the inner surface of the tongue receiving hole 2b and the inner surface contact surface of the latch tongue 13a get closer to each other as the latch tongue 13a enters into the tongue receiving hole 2b. Thus, the tapered surface comes in contact with the inner surface of the tongue receiving hole 2b when the latch tongue 13a enters into the receiving hole to some extent, and a biasing force perpendicular to the longitudinal direction of the latch tongue 13a acts between the latch tongue 13a and the inner surface of the tongue receiving hole 2b as the latch tongue 13a further enters into the tongue receiving hole 2b, whereby engagement and fixation of the lid 3 and the pod main body 2 is achieved. In this case, in the state in which the latch tongue 13a is at its final position in the tongue receiving hole 2b, at least one of the latch tongue 13a and the lid 3 has been displaced or shifted in a direction different from the longitudinal direction of the latch tongue 13a by the effect of the biasing force. Alternatively, a tapered surface may be provided on the base portion of the latch bar 13 and the disk 15 etc. to serve as a cam and a cam follower so that the latch tongue 13a is displaced or shifted in a direction different from the longitudinal direction of the latch tongue 13a (more specifically, in a direction toward the inner surface of the tongue receiving hole 2b) at the time when the latch tongue 13a enters into the interior of the tongue receiving hole 2b to the largest extent. In this case also, in the state in which the latch tongue 13a is at its final position in the tongue receiving hole 2b, at least one of the latch tongue 13a and the lid 3 has been displaced or shifted in a direction different from the longitudinal direction of the latch tongue 13a by the effect of the biasing force.

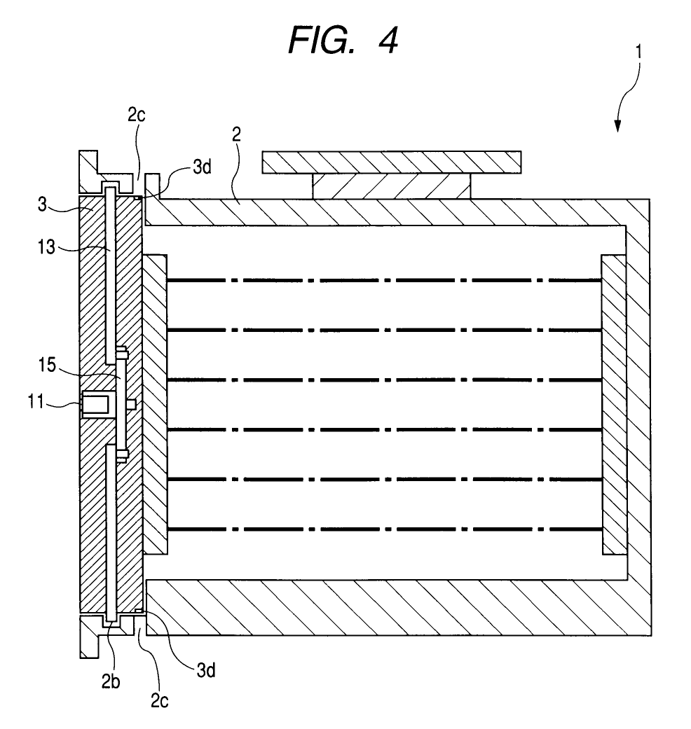

An embodiment of the present invention will be described in the following with reference to the drawings. FIG. 4 shows, in a manner similar to FIG. 3, a pod or a closed container according to an embodiment of the present invention. In FIG. 4, components having the same functions as those in the pod shown in FIG. 3 will be designated by the same reference numerals, and they will not be described in further detail. In the following, characteristic portions of the present invention that are different from the conventional design shown in FIG. 3 will be described. In this embodiment of the present invention, a detection mark 3d made of a material having a characteristic such as a reflectance or color etc. that is different from the material of the lid 3 is provided on a predetermined position on the outer peripheral surface 3b of the lid 3. The pod main body 2 is provided with a detection window 2c through which the detection mark 3d can be detected only in the state in which the lid 3 is fixed at a right position on the pod body 2. After the lid 3 has been fixed on the pod main body 2 by the latch mechanisms 10, it can be detected whether the lid 3 is fixed in an appropriate state on the pod main body 2 by checking whether the detection mark 3d is located at a right position through the detection window 2c using a physical method such as optical detection based on light reflected from the mark 3d or detection using a contact sensor.

As described above, when the lid 3 is actually fixed to the pod main body 2, it is preferred that a biasing force acts on the latch tongue 13a or the latch tongue receiving hole 2b at a final stage of fixation of the lid 3 to the pod main body 2. As a result, the lid 3 or the latch tongue 13a is displaced or shifted in a direction different from the longitudinal direction of the latch tongue 13a (more specifically, in a direction perpendicular to the longitudinal direction), whereby the components are positioned appropriately. Therefore, it is preferred that the positions of the detection window 2c and the corresponding detection mark 3d be arranged in such a way that the detection mark 3d can be detected through the detection window 2c in the state in which they are positioned appropriately after the displacement (or shift). If the detection mark 3d is arranged in such a way as to be detectable at the position after the displacement, an operation in a direction perpendicular to the distance direction between sensor and marks in proximity position can be easily detection. It is difficult to detect such an operation by, for example, a proximity sensor using a magnetic method. Actually, engagement or fixation of the lid 3 and the pod main body 2 is achieved by such an operation in the perpendicular direction, and it is possible to easily detect whether or not successful fixation has been achieved.

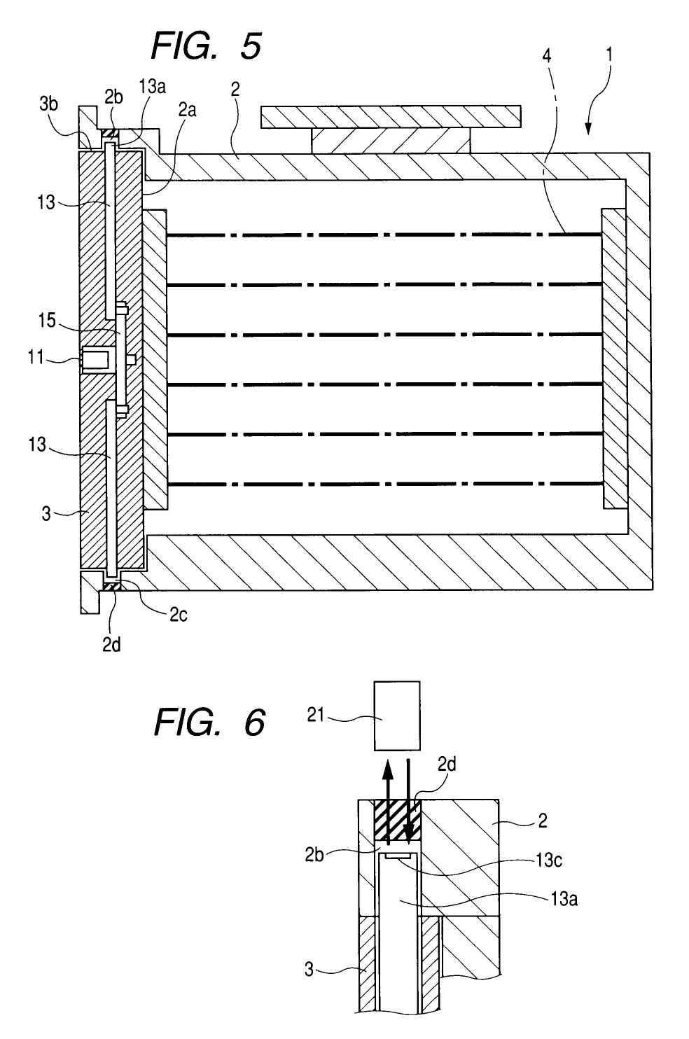

A detection mark(s) like the above described detection mark 3d may be provided on the latch tongue(s) 13a. Such a case is shown in FIG. 5 in a manner similar to FIG. 3. FIG. 6 is an enlarged view of a portion including the latch tongue 13a. In FIGS. 5 and 6, components having the same functions as those in the conventional pod shown in FIG. 3 will be designated by the same reference numerals, and they will not be described in further detail. In this embodiment, a detection window 2c is provided continuously with the tongue receiving hole 2b so as to align the detection window 2c and the tongue receiving hole 2b in one direction, and the end portion of the latch tongue 13a can be observed through the detection window 2c. On the end of the latch tongue 13a is provided a detection mark 13c that can reflect light used by an optical sensor 21.

In this embodiment, in order to prevent a gas flow passage leading to the mini environment through the detection window 2c, the tongue receiving hole 2b, and the bore in which the latch bar 13 is accommodated etc. from being formed, a transparent closing member 2d made of a resin or the like is provided in the opening portion of the detection window 2c to close or stop the detection window 2c while allowing observation or detection of the latch tongue 13a. According to this embodiment, it is possible to know accurately and reliably whether or not the latch tongue 13a is received in the tongue receiving hole 2a, namely whether or not the lid 3 is fixed to the main body 2. This mode of the invention can be implemented only by providing a conventional load port apparatus with an optical sensor in the vicinity of the opening portion of the mini environment. Therefore, this mode is advantageous in that it can be implemented easily in a conventional apparatus.

It is preferred that the detection mark 13c be composed of a reflecting member, as described above. The reflecting member may be a regular reflector or a retroreflector. Although in the arrangement illustrated in FIG. 6, the optical axis of the optical sensor 21 in emitting and receiving light is perpendicular to the surface of the detection mark 13c, the optical, the optical axis of the optical sensor 21 may be inclined relative to the normal line of the detection mark 13c. In a case where the optical axis of the optical sensor 21 is inclined, the sensor may be arranged in such a way that it is not until the latch tongue 13a is inserted to a predetermined position in the tongue receiving hole 2b that light reflected by the mark 13c is received by the sensor. By this arrangement, the state of the latch tongue 13a can be detected more accurately. Alternatively, the optical sensor 21 may be a range sensor, and the state of the latch tongue 13a may be detected based on the measured distance.

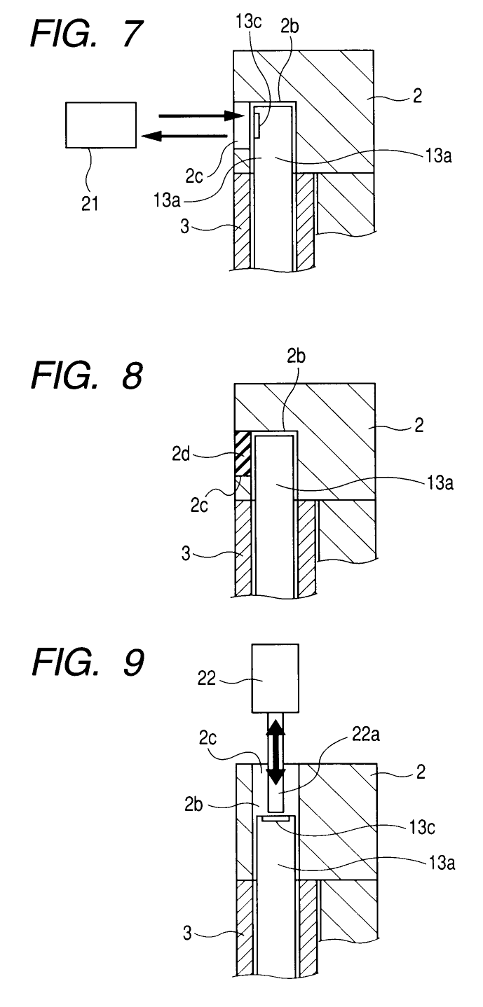

Although in this embodiment, the detection mark 13c is provided at the end portion (specifically, on the end face) of the latch tongue 13a, the detection mark may be provided on a side surface of the end portion as shown in FIG. 7. FIG. 7 shows such an embodiment in a manner similar to FIG. 6. In this embodiment, the detection window 2c extends from the end face of the opening side of the pod main body 2 to the tongue receiving hole 2b along the direction perpendicular to the direction along which the tongue receiving hole 2b is provided (or the direction along which the latch bar 13 extends). More specifically, the position of the detection window 2c is designed in such a way that it is not until the latch tongue 13a is inserted to a predetermined position in the tongue receiving hole 2b to fix the lid 3 to the main body 2 that the detection mark 13c can be observed or detected through the detection window 2c. By providing the detection window 2c at this position, it is possible to know accurately whether or not the latch tongue 13a functions successfully by detecting the presence/absence of the detection mark 13c at the predetermined position by the optical sensor 21.

In this embodiment also, a closing member 2d may be provided so that the detection window 2c is closed physically but left open optically, for the same reason as the arrangement shown in FIG. 6. Such an embodiment is shown in FIG. 8. FIG. 8 shows such an embodiment in a manner similar to FIG. 6. In the embodiments shown in FIGS. 7 and 8, it is necessary to consider how an optical sensor is attached on the load port apparatus. However, whether the latching function of the latch tongue 13a is successively achieved or not can be determined based on a determination as to whether the detection mark 13c can be observed or not. Therefore, these embodiments are advantageous in that the latching state can be detected only by detecting presence/absence of reflected light using an optical sensor.

Although in the above described embodiments, the detection window 2c is disposed in such a way as to be aligned with the tongue receiving hole 2b or provided continuously with the end portion of the tongue receiving hole 2b, the position of the detection window 2c according to the present invention is not limited to them. For example, there may be provided a detection window 2c that extends to the tongue receiving hole 2c from the side surface of the pod distant from the hole 2c instead of a detection window 2c like those in the above described embodiments provided between the tongue receiving hole 2c and the outer surface of the pod main body 2 that is closest to the hole 2c. In other words, the detection window may be arranged to open in any direction as long as it is possible to detect whether the latch tongue 13a is located at an appropriate position or not. Alternatively, the pod may be made of a transparent material so that the latch tongue 13a can be observed from all the directions.

Although the detection mark 13c provided as a flat region extending perpendicularly to the longitudinal direction of the latch bar 13 has been described by way of example in this embodiment, the mode of the present invention is not limited to this. For example, as described before, it is commonly considered to be preferred that the latch tongue 13a be biased in a direction perpendicular to the longitudinal direction of the latch bar 13 after sliding in the longitudinal direction, to achieve reliable engagement with the pod main body 2, and perform an operation that causes a little axial shift. In this case, the shape of the detection mark 13c may be selected from various shapes such as a spot, line etc. or the position of the detection mark 13c may be adjusted so that the sensor can detect the presence/absence of the detection mark 13c upon the aforementioned shift operation or detect the shift. For example, completion of the latching operation may be determined when the detection mark 13c in the form of e.g. a line crosses the detection area or spot of the optical sensor by processing a signal generated by the optical sensor. Thus, the latching state can be detected with improved reliability. The detection mark 13c may be formed simply by coloring the latch tongue 13a or coloring a part thereof. In this case, by arranging the positions of the detection window 2c and the detection mark 3d appropriately relative to each other so that the detection mark 3d can be detected only when the latch tongue 13a is in the final position in engagement as described above, the latching state can be detected more reliably.

In the above described embodiment, the detection mark is detected by an optical sensor. However the preset invention is not limited to this, but a contact sensor may be used as shown in FIG. 9. FIG. 9 shows another embodiment in a manner similar to FIG. 6. The detection window 2c is provided continuously with the tongue receiving hole 2b, and a detection pin 22a of the contact sensor 22 is inserted through the detection window 2c toward the tongue receiving hole 2b. The detection mark 13c provided on the end of the latch tongue 13a comes in contact with the end of the detection pin 22a, and the pin 22a is depressed by the latch tongue 13a, whereby it is determined whether or not the latch tongue 13a is at the right position. In this embodiment, it is necessary to dispose the contact sensor 22 in such a way that the detection pin 22a can be inserted into the detection window 2c in a state in which the pod main body 2 is set at a predetermine position for opening/closing the lid 3. In addition, it is necessary to perform an operation of inserting the detection pin 22a at an appropriate time. Therefore, the structure of the apparatus may be complex to some extent. However, this embodiment is advantageous in that the possibility of malfunction of the sensor is much lower than the optical sensor, which has various factors that lead to malfunction, such as stain on the closing member and stray light etc.

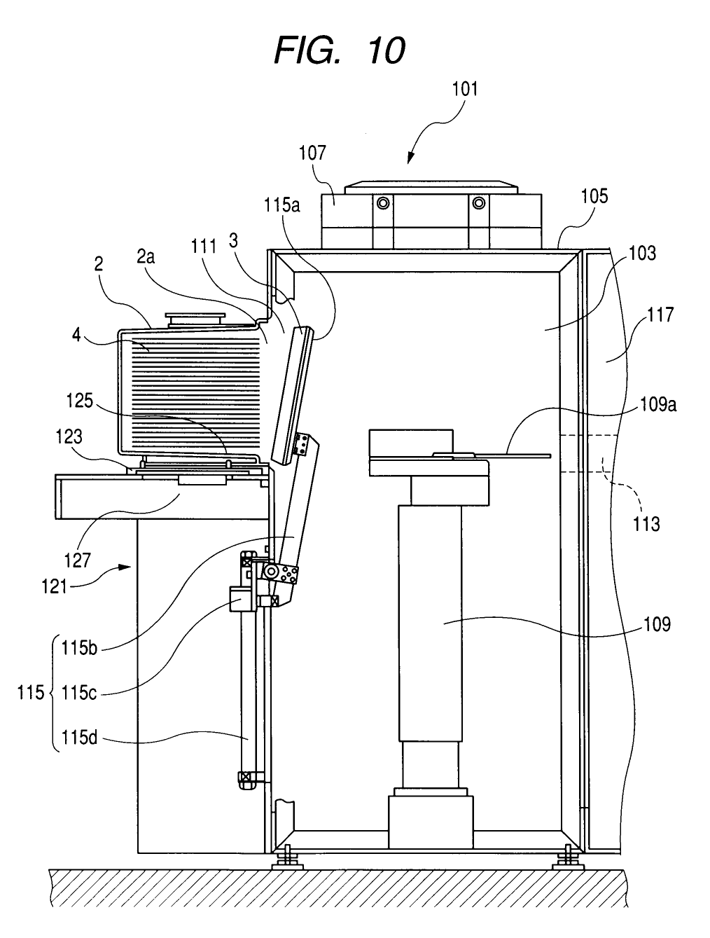

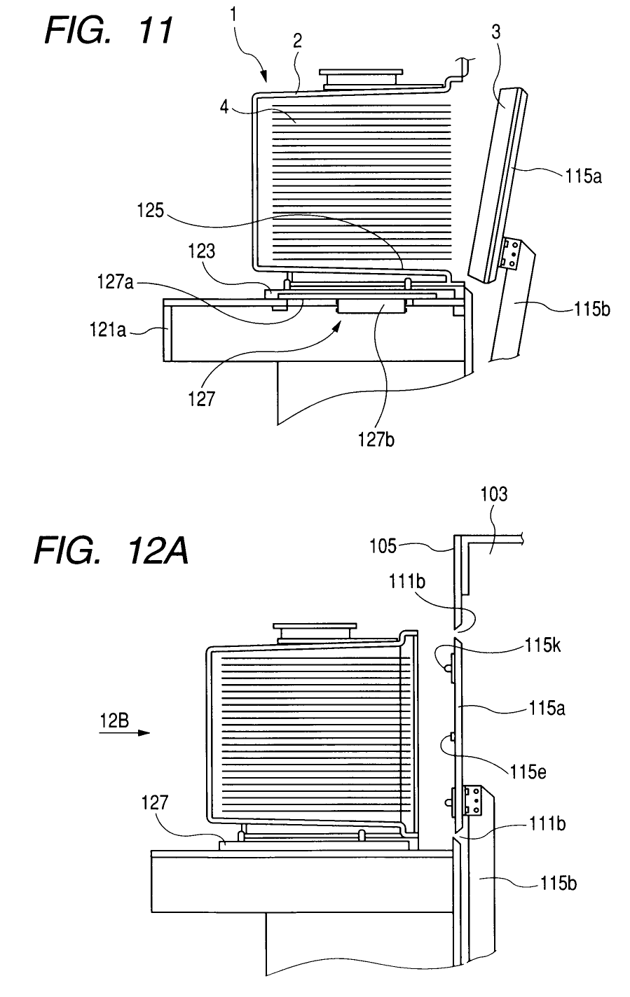

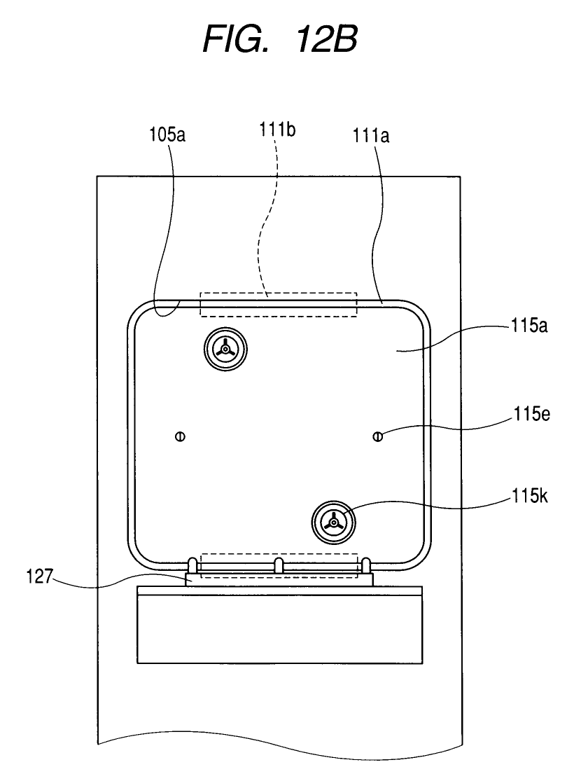

In the following, a lid opening and closing system for a closed container that corresponds to the above-described pod according to the present invention will be described. FIG. 10 is a side cross sectional view showing the general structure of the system. FIG. 11 is an enlarged view showing a pod support portion, a door, a pod and a lid etc. in this system 101 in a similar manner. FIG. 12A schematically shows the pod support portion and the door etc. in the state in which the opening of the pod is closed by the lid. FIG. 12B schematically shows the surface of the door etc. as seen from the direction of arrow 12B in FIG. 12A.

The FIMS system 101 has a cabinet 105 that defines a mini-environment 103 and a pod support portion 121 provided adjacent to the cabinet 105. The cabinet 105 is further provided with a fan 107, a robot 109, a first opening portion 111, a second opening portion 113, and a door system 115. The fan 107 is provided on the cabinet 105 in the upper portion of the mini-environment 103 to introduce the air in the space outside the cabinet 105 into the mini-environment. The bottom portion of the cabinet 105 has a structure that allows air to flow out of the cabinet 105 to the exterior. Thus, dust particles or the like generated in the mini-environment 103 are brought by the air flow and discharged to the exterior space through the bottom of the cabinet 105. A robot arm 109a of the robot 109 can be extended to the exterior of the mini-environment through the first opening portion 111 and the second opening portion 113. The first opening portion 111 is closed, in a way, by the door 115a of the door system 115, where a gap is left between the outer periphery of the door 115a and the inner peripheral surface of the first opening portion 111. Thus, it should be said that the door 15a can nearly close the first opening portion 111. The second opening portion 113 leads to the interior of a wafer processing apparatus 117. The details of the wafer processing apparatus 117 will not be described in this specification, because they have no direct bearing on the present invention.

The pod support portion 121 has a docking plate 123, a pod fixing system 125 and a docking plate drive system 127. The upper surface of the docking plate 123 is substantially flat, and some portions of the pod fixing system 125 is provided thereon. A pod 1 according to the present invention is placed on the upper surface of the docking plate 123, and the aforementioned portions (specifically, pins) of the pod fixing system 125 come into engagement with engaged portions (not shown) provided on the bottom surface of the pod 1 to fix the pod 1 at a predetermined position on the docking plate 123. The docking plate 123 is configured in such a way that the opening 2a of the main body of the pod 1 is just opposed to the above described first opening portion 111 when the pod 1 is placed on the upper surface of the docking plate 123. The docking plate drive system 127 drives the docking plate 123 and the pod 1 fixed at the predetermined position thereon toward/away from the first opening portion 111 using a guide rail 127a and a driving cylinder 127b.

One end of the driving cylinder 127b is fixed to the body 121a of the support table, and the other end or the cylinder end that can extend/retract is fixed to the docking plate 123. The docking plate 123 is supported on the guide rail 127a in a slidable manner so that it can slide on the guide rail 127a with extension/retraction of the cylinder end of the driving cylinder 127b. The docking plate 123 is located farthest from the mini environment 103 when it is at the position at which the pod 1 is placed on (or loaded on) it and removed from (or unloaded from) it, and located closest to the mini environment 103 when it is at the position at which the lid 3 of the pod 1 is to be detached from the pod 1.

On the exterior space side surface of the door 115a (i.e. the surface of the door that faces the pod 1) are provided the aforementioned latch keys 115e as shown in FIGS. 12A and 12B. Each latch key 115e is inserted into the corresponding key receiving hole 15b of the latch mechanism 10 provided on the front side surface of the lid 3 of the pod 1 and causes the disk 15 to rotate, thereby retracting the aforementioned latch tongue 13a from the tongue receiving hole 2b provided on the pod main body 2, whereby the lid 3 is allowed to be attached/detached to/from the pod main body 2.

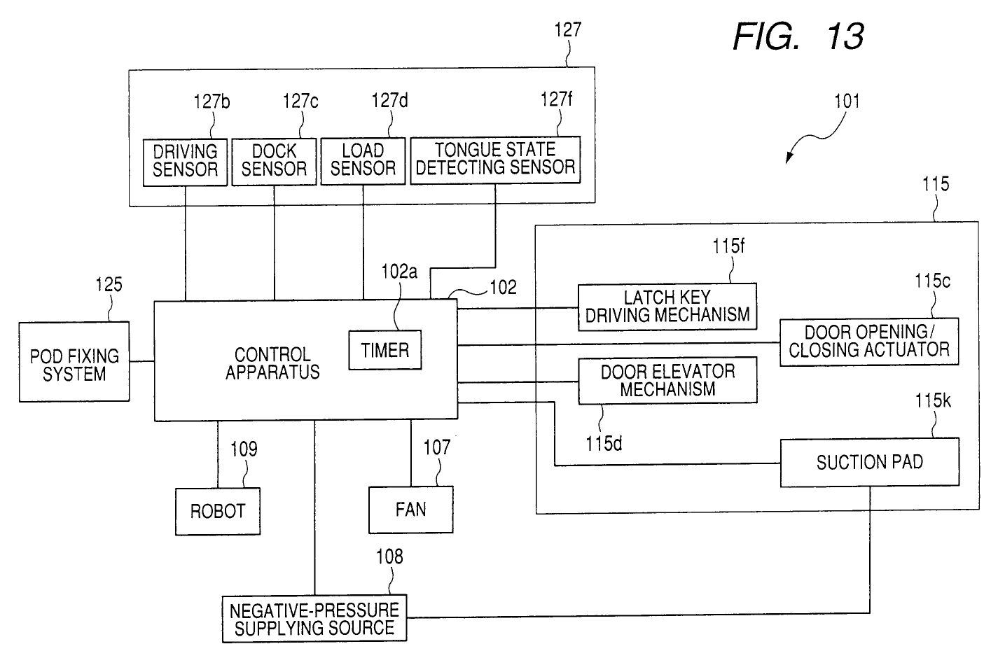

Suction pads 115k are supplied with a negative pressure from a negative pressure supplying source 108 (see FIG. 13) through pipes (not shown) when they are in contact with the lid 3, whereby the lid 3 can be sucked by the suction pads 115k. Thus, the lid 3 can be held by the door 115a. The door system 115 includes a door arm 115b, a door opening/closing actuator 115c and a door elevator mechanism 115d. The door arm 115b is a rod-like member, which supports the door 115a at one end and is connected to the door opening/closing actuator 115c at the other end. The door arm 115b is pivotally supported by a pivot shaft at an appropriate intermediate position thereof so as to be able to swing about that position. The door arm 115b is swung about the rotation center axis by the door opening/closing actuator 115c, whereby the end of the door arm 115b and the door 115a supported thereon are moved toward or away from the first opening 111. The door elevator mechanism 115d supports the door opening/closing actuator 115c and the pivot shaft of the door arm 115b and has a vertical movement actuator to move the actuator, the door arm 115b supported thereon, and the door 115a in the vertical direction along a guide extending in the vertical direction. The latch key 115e is connected with a latch key drive mechanism 115f (FIG. 13), and rotated in the forward and backward directions by the latch key drive mechanism 115f within a certain angular range.

FIG. 13 is a block diagram showing the configuration of the FIMS system 101. The above described fan 107, robot 109, door system 115, pod fixing system 125, and docking plate drive system 127 are controlled by a control apparatus 102. The latch key drive mechanism 115f, the door opening/closing actuator 115c and the door elevator mechanism 115d in the door system 115 may be controlled independently from each other. However, in the actual operation, they are controlled in such a way that they operate according to a sequence time chart. Supply of negative pressure to the suction pads 115k from the negative pressure supplying source 108 and shutting-off thereof (breaking of the negative pressure) are controlled by the control apparatus 102. The docking plate drive system 127 turns on and off the operation of the driving cylinder 127b. It is necessary to detect, with reliability, two predetermined positions of the docking plate 123 driven by the operation of the driving cylinder 127b, namely the load position that allows placement of the pod 1 and the dock position that allows transfer of wafers from/into the pod 1.

For this purpose, the docking plate drive system 127 is connected with a load sensor 127d that detects placement of the pod 1 on the docking plate 123 and presence of the docking plate 123 at the position that allows loading/unloading of the pod 1 onto/from the docking plate 123. In addition, the docking plate drive system 127 is also connected with a dock sensor 127c that detects whether or not the docking plate 123 is located at the above described dock position. According to the present invention, a tongue state detecting sensor 127f in the form of, for example, the above described optical sensor etc. that detects the state of the latch tongue 13a is provided in addition to the ordinary sensors mentioned above.

In this embodiment, it is detected by the tongue state detecting sensor 127f whether or not the latch tongue 13a has been inserted into the tongue receiving hole 2b in an appropriate state, and a determination as to whether fixing of the lid 3 on the pod main body 2 is successful or not is made based on the detection result. In normal cases, if the detection result indicates that the fixing is successful, the ordinary operation for unloading the pod 1 is performed. If the detection result indicates that the fixing is unsuccessful, or fixation of the lid 3 to the pod main body 2 has not been achieved, and there is a possibility of detachment of the lid 3 during transportation etc, the lid 3 is once detached from the pod main body 2, and the operation of fixing the lid 3 is performed again. Thereafter, the detection of the state of the latch tongue 13a is performed again.

In the following, the operation of the FIMS system 101 in actual wafer processing operations will be described. In wafer processing operations, a pod 1 containing a certain number of wafers and filled with clean gas is placed on the docking plate 123. When the pod 1 is placed on the docking plate 123, the pod fixing system 125 operates to locate the pod 1 at a predetermined position on the docking plate 123. Thereafter, the docking plate drive system 127 operates to move the pod 1 toward the first opening portion 111. Specifically, the pod 1 that has been made integral with the docking plate 123 by the pod fixing system 125 is moved by driving the docking plate 123 using the driving cylinder 127b. During this operation, the door 115a is kept stationary at the position at which it substantially closes the first opening portion 111. The driving operation is completed when the lid 3 of the pod 1 abuts the abutment surface of the door 115a, and a predetermined positional relationship between the docking plate 123 and the first opening portion 111 is achieved. At this time, each latch key 115e of the latch key drive mechanism 115f is inserted into the key receiving hole 15b exposed on the front side surface of the lid 3 and causes the disk 15 to rotate, whereby the lid 3 is brought into a state in which it can be attached/detached to/from the pod main body 2. Simultaneously, the suction pads 15k suck the lid 3, whereby the lid 3 is held by the door 115a.

In this state, the door opening and closing actuator 115c starts to operate. Thus, the door arm 115b swings to move the door 115a that is holding the lid 3 from the first opening portion 111 to the interior of the mini environment 103. When the door arm 115b stops swinging at a predetermined swing angle, the door elevator mechanism 115d starts to operate, whereby the door 115a is moved downward with the door opening/closing actuator 115c. By this operation, the first opening portion 111 is fully opened, and the mini environment 103 is in communication with the interior of the pod main body 2 via the first opening portion 111. In this state, the robot 109 starts to operate, and transfers wafers 4 from the interior of the pod 1 to the wafer processing apparatus 117 through the second opening portion 113, using the robot arm 109a. Furthermore, while this state is maintained, the robot 109 also transfers wafers that have undergone a certain processing in the interior of the wafer processing apparatus 117 into the interior of the pod 1. By reversing the above procedure basically, the lid 3 is attached to the pod 1, and the pod 1 can be detached from the FIMS system 101. According to the present invention, after the lid 3 has been attached to the pod 1, it is detected or checked, by the tongue state detecting sensor 127f, whether or not the latch tongue 13a is successfully received in the tongue receiving hole 2b. If the latch tongue 13a is successfully received in the tongue receiving hole 2b, then the pod 1 is moved.

In the following, a detailed description will be made of a method for detecting the fixing state of the lid more accurately by additionally performing the operation of directly applying a load on the lid after carrying out the operation according to the present invention in the load port apparatus 101 having the above described configuration. Typically, the pod 1 is unloaded (or brought into a state in which it can be removed) from the FIMS system 101 by reversing the procedure of loading (attaching the pod to the support table). However, in the conventional apparatus, it is difficult to check whether the lid 3 is fixed steadily on the pod main body 2 or not. Even in the case of an apparatus in which the present invention is implemented (e.g. in the embodiment shown in FIG. 6), there is a possibility that detection error cannot be eliminated completely or a high degree of accuracy in detection cannot be achieved, only by simply detecting the detection mark 13c using an optical sensor.

In this embodiment, whether the lid 3 is successfully fixed on the pod main body 2 or not is determined by a method other than direct detection of the latch tongue. In this method, the operations described below are performed in sequence. By carrying out this method in addition to the direct detection of the latch tongue, the fixing state of the lid 3 on the pod main body 2 can be checked with improved reliability. In this embodiment, the detection mark 13c is detected using an optical sensor. In the pod and the load port used in this embodiment, the detection mark 13c extends in a direction perpendicular to the optical axis of the optical sensor, as is the case with the embodiments shown in FIGS. 6, 7, and 8.

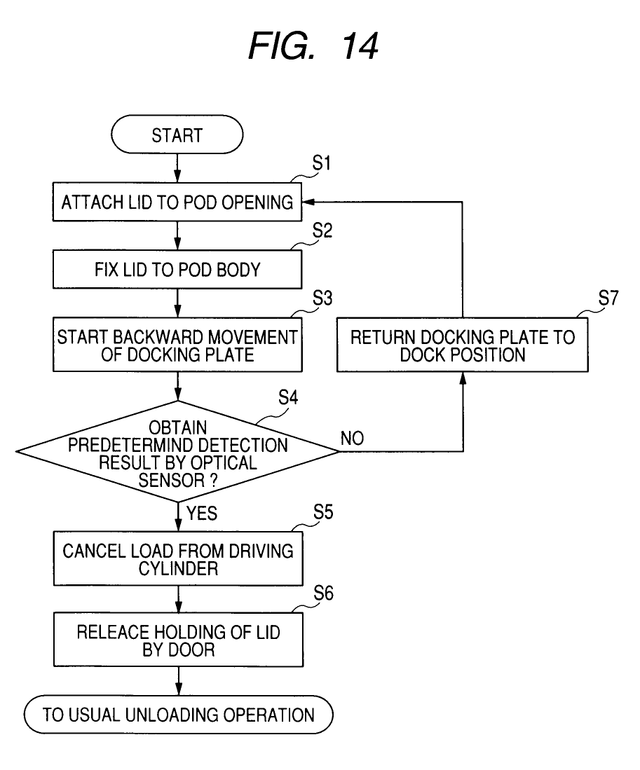

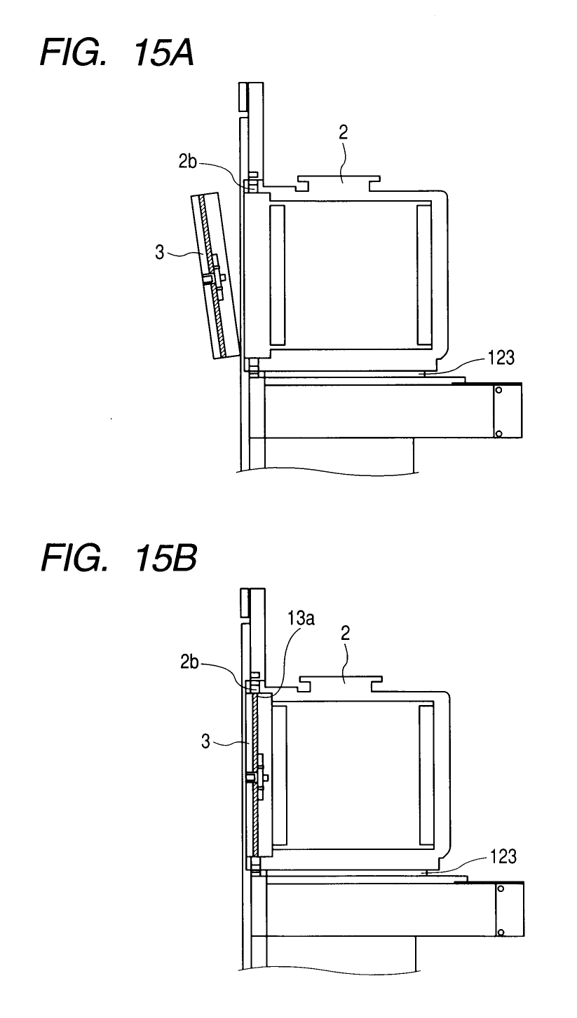

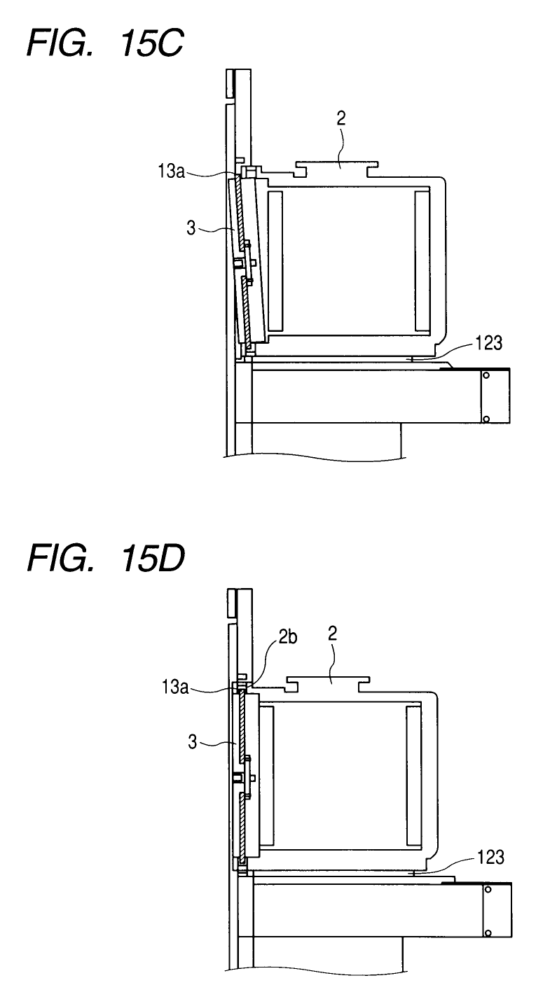

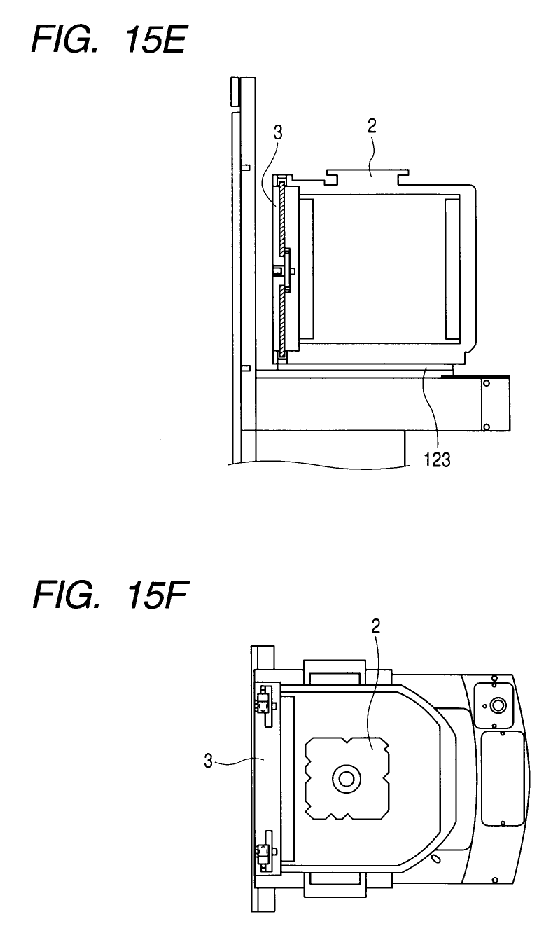

In the following, the operations executed by a control apparatus 102 will be described with reference to the flow chart of FIG. 14. FIGS. 15A to 15E show the pod main body 2, the lid 3, and the docking plate 123 supporting them etc. at some stages in the operation process in a manner similar to FIGS. 4 and 11. FIG. 15F is a top view of the pod 1 and other components in the state shown in FIG. 15D. First, the door system 115 is actuated to attach the lid 3 to the opening 2 of the pod main body 2 resting at the dock position (step S1, FIG. 15A). At the time when it is determined that the lid 3 comes nearly to a predetermined position in relation to the pod opening 2a (FIG. 15B), the latch keys 115e are actuated, whereby the latch tongues 13a provided in the lid 3 are extended and inserted into the tongue receiving holes 2b provided on the pod main body 2. Thus, the lid 3 is fixed to the pod main body 2 by engagement of the latch tongues 13a with the inner surface of the tongue receiving holes 2b (step S2, FIGS. 15D and 15E).

According to conventional operation methods, upon completion of extension of the latch tongues 13a, holding of the lid 3 by the suction pads 115k is released, and the backward movement of the docking plate 123 is started. In this embodiment, in contrast to this, holding of the lid 3 by the suction pads 115k is maintained even after completion of the tongue extending operation, and the operation for backwardly moving the docking plate 115k is performed for a while (step S3). In normal cases, when the pod 1 or the docking plate 123 is displaced from the dock position with the backward movement of the docking plate 115k, the tongue state detecting sensor 127f (i.e. the optical sensor 21 in FIGS. 6 and 7) indicates displacement of the detection mark 13c from the detectable position, in other words the sensor 127f generates a signal indicative of the fact that the latch tongue 13a is not located at the predetermined position. In this embodiment, the force of holding the lid 3 by the suction pads 115k is designed to be weaker than the driving force exerted by the driving cylinder 127b to move the docking plate 23 etc.

In contrast, if the fixation of the lid 3 to the pod main body 2 is unsuccessful (FIG. 15C), specifically, if one or some of the latch tongues 13a are not appropriately inserted or received in the tongue receiving holes 2b, it is detected by the tongue state detecting sensor 127f that the one or some of the detection marks 13c do not change their positions, because the lid 3 can be separated from the pod main body 2 again. This process is executed in step S4 of the flow chart, where it is checked whether or not the lid 3 has been displaced relative to the pod main body 2 by determining whether a predetermined detection result is obtained by the tongue state detecting sensor 127f. In addition, if it is confirmed, based on a signal from the dock sensor 127c, that the pod main body 2 has been displaced backwardly, it can be determined more reliably that the pod main body 2 and the lid 3 have moved differently from each other.

More specifically, if the predetermined detection result is obtained by the tongue state detecting sensor 127f and displacement of the pod main body 2 is detected by the dock sensor 127c during a lapse of a specific time measured by a timer 102a provided in the control apparatus 102 since the start of the operation of the driving cylinder 127b, it is determined that the lid 3 is fixed on the pod main body 2 appropriately. Then, the process proceeds to step S5, where the driving force exerted on the docking plate 123 by the driving cylinder 127b is once canceled in this state, and thereafter ordinary operations for unloading the pod 1, such as release of holding of the lid 3 by the suction pads 115k (S6), are performed (FIG. 15E). On the other hand, if a signal indicative of the predetermined detection result has not been received from the tongue state detecting sensor 127f after a lapse of the aforementioned specific time, it is determined that fixation of the lid 3 on the pod main body 2 is unsuccessful. In this case, the driving cylinder 127b is operated in the reverse direction to return the docking plate 123 etc. to the dock position again (S7). Thereafter, the process starting from step S1 is executed again. The process is executed repeatedly until it is determined that the lid 3 is fixed on the pod main body 2 appropriately. Alternatively, it is determined that the fixation of the lid 3 is defective, and the control apparatus 102 outputs an alarm signal to inform an operator of this.

By performing the above-described lid opening and closing method for a pod according to this embodiment on the above-described pod and load port, it is possible to check easily and reliably whether the lid is fixed appropriately on the pod or not. Advantageously, the present invention can be implemented only by adding a process step of making a determination as to a signal from the tongue state detecting sensor 127f which is available in conventional apparatuses, a loop for performing the operation of fixing the lid again according to the result of the determination, and a step of once releasing the load applied by the driving cylinder, to the operation flow in conventional apparatuses.

In the above described embodiment, the dock sensor 127c is used as displacement detection means for detecting displacement of the docking plate 123 etc. However, in a case, for example, where the pod has such a shape in which the opening side is projecting, appropriate detection of displacement by the dock sensor 127c may be impossible due to its position. In this case, use may be made of not only a signal from the dock sensor but also a signal from what is called an undock sensor (not shown) that is provided to detect a certain amount of displacement of the docking plate from the dock position. By using two position signals from the dock sensor and the undock sensor, whether the pod main body 2 is displaced or not can be determined based on a displacement of the pod in a specific zone according to the type of the pod used. Therefore, the state of fixation of the lid on the pod can be checked by carrying out the above described method irrespective of the shape of the pod.

Although in the above described embodiments, suction pads 115k are used as lid holding means, the lid holding means is not limited to the suction pads, but other various means such as holding means using a latch may be used. If other lid holding means is used, it is preferred that the docking plate driving means and the lid holding means be designed in such a way that the driving force of the driving cylinder 127b is stronger than the lid holding force of the lid holding means in the process of determining the state of fixation of the lid. However, even if the driving force is weaker than the holding force, it is possible to determine whether the state of fixation of the lid is appropriate or not based on a signal from the dock sensor. Specifically, if a signal indicative of the movement of the docking plate is not generated by the dock sensor even though the driving force is exerted on the docking plate, it may be determined that the lid 3 is appropriately or successfully fixed on the pod main body 2. On the other hand, if the plate is moved or displaced or the signal designating the movement of the plate is generated, when the driving force is exerted thereon, it may be determined that the lid is not appropriately fixed on the pod main body.

As described above, although in the case of the above described embodiments, the lid 3 is held by the suction pads 115k with a force weaker than the force with which the docking plate 123 is driven by the drive cylinder 127b, the holding force may be designed to be stronger than the driving force. In cases where the holding force is designed to be stronger than the driving force, a change in the position of one or some of the detection marks 13c will be detected if one or some of the latch tongues 13a are not inserted or received appropriately in the tongue receiving holes 2b and the lid 3 and the pod can be separated again. If the latch tongues 13a are inserted or received appropriately in the tongue receiving holes 2b, the lid 3 cannot be moved because it is held by the door 115a, and therefore the positions of all the detection marks 13c will not change.

In the foregoing, the present invention has been described in connection with an FIMS system for wafers. However, the applications of the invention are not limited to that system, but the present invention can also be applied, for example, to closed containers for storing display panels, optical disks or the like.

As many apparently widely different embodiments of the present invention can be made without departing from the spirit and scope thereof, it is to be understood that the invention is not limited to the specific embodiments thereof except as defined in the appended claims.

What is claimed is:

1. A closed container comprising:
a lid having a flat plate-like shape; and
a main body having an opening to be closed by said lid on one lateral side thereof in which an object to be stored can be stored, wherein
said lid has a latch mechanism including a latch tongue that is caused to project from said flat plate-like shape by an operation from outside and a detection mark that is disposed at an end portion of said latch tongue and can reflect a sensor light of a specific sensor that detects presence/absence of an object by projecting and receiving the sensor light, and
said main body has a tongue receiving hole in which the latch tongue projecting from said flat plate-like shape of said lid can be received so that fixation of said lid and said main body is achieved by engagement of said latch tongue with the tongue receiving hole in a biased state, and a detection window disposed at a position that allows said specific sensor to project said sensor light to said detection mark and to receive said sensor light from said detection mark in a state in which said latch tongue is engaging with said tongue receiving hole while biased.

2. A closed container according to claim 1, wherein an open portion of said detection window is stopped by a transparent closing member.

3. A closed container according to claim 1, wherein said detection window is provided on said main body along a direction perpendicular to a direction in which said latch tongue extends.

4. A lid opening and closing system that opens and closes said lid of a closed container as recited in claim 1 to allow transfer of said object to be stored into/out of the interior of said closed container, comprising:
a mini environment having an opening portion;
a door that can move between a position at which it closes said opening portion and a position at which it leaves said opening portion open and has lid holding means for holding said lid and a latch key that can operate said latch mechanism;
a docking plate on which said closed container can be placed in such a way that said opening is opposed to said opening portion and that can move toward and away from said opening portion with said closed container thereby disposing, when located at a position close to said opening portion, said closed container at a position at which said lid is to be detached and transfer of said object to be stored into/out of it is to be performed, and disposing, when located at a position away from said opening portion, said closed container at a position at which loading and unloading of said closed container is to be performed;
docking plate driving means for causing said docking plate to move toward and away from said opening portion; and
said specific sensor that can detect presence of said detection mark in said tongue receiving hole by projecting said sensor light into the interior of said tongue receiving hole and receiving said sensor light from the interior of said tongue receiving hole through said detection window.

5. A wafer transfer system comprising a closed container as recited in claim 1 and a lid opening and closing system according to claim 4 that opens and closes said lid of said closed container to allow transfer of said object to be stored into/out of the interior of said closed container, wherein said object to be stored is a wafer.

6. A closed container comprising:
a lid having a flat plate-like shape; and
a main body having an opening to be closed by said lid on one lateral side thereof in which an object to be stored can be stored, wherein
said lid has a latch mechanism including a latch tongue that is caused to project from said flat plate-like shape in a direction in which it extends and biased to shift in a direction different from said direction in which it extends by an operation from outside and a detection mark that can be detected in terms of presence/absence thereof by a specific sensor,
said main body has a tongue receiving hole in which the latch tongue projecting from said flat plate-like shape of said lid can be received and a detection window that allows said specific sensor to detect the presence of said detection mark at a predetermined position in a state in which said lid is fixed to said main body by the insertion of said latch tongue into said tongue receiving hole and said shit of said latch tongue, and said specific sensor is a sensor using light, and
said detection mark comprises a member that reflects light.

7. A closed container according to claim 6, wherein said detection mark is provided on said latch tongue.

8. A lid closing method, which is applied to a lid opening and closing system that opens and closes a lid of a closed container including the lid having a flat plate-like shape and a main body having an opening to be closed by said lid on one lateral side thereof in which an object to be stored can be stored to allow transfer of said object to be stored into/out of the interior of said closed container, for closing said opening by said lid, said lid having a latch mechanism including a latch tongue that is caused to project from said flat plate-like shape by an operation from outside and a detection mark that is disposed at an end portion of said latch tongue and can reflect a sensor light of a specific sensor that detects presence/absence of an object by projecting and receiving the sensor light, said main body having a tongue receiving hole in which the latch tongue projecting from said flat plate-like shape of said lid can be received so that fixation of said lid and said main body is achieved by engagement of said latch tongue with the tongue receiving hole in a biased state, and a detection window disposed at a position that allows said specific sensor to project said sensor light to said detection mark and to receive said sensor light from said detection mark in a state in which said latch tongue is engaging with said tongue receiving hole while biased, and said lid opening and closing system having a mini environment having an opening portion, a door that can move between a position at which it closes said opening portion and a position at which it leaves said opening portion open and has lid holding means for holding said lid and a latch key that can operate said latch mechanism, a docking plate on which said closed container can be placed in such a way that said opening is opposed to said opening portion and that can move toward and away from said opening portion with said closed container thereby disposing, when located at a position close to said opening portion, said closed container at a position at which said lid is to be detached and transfer of said object to be stored into/out of it is to be performed, and disposing, when located at a position away from said opening portion, said closed container at a position at which loading and unloading of said closed container is to be performed, docking plate driving means for causing said docking plate to move toward and away from said opening portion, and said specific sensor that can detect presence of said detection mark in said tongue receiving hole by projecting said sensor light into the interior of said tongue receiving hole and receiving said sensor light from the interior of said tongue receiving hole through said detection window, the method comprising the steps of:
setting said lid at a position at which it closes said opening by operating said door;
inserting said latch tongue into said tongue receiving hole by operating said latch mechanism by said latch key so that said lid will be fixed on said closed container;
detecting the presence of said detection mark at a predetermined position, by said specific sensor;
causing said docking plate driving means to operate in such a way as to displace said docking plate from said position close to the opening portion while maintaining holding of said lid by said door;
detecting displacement of said docking plate and displacement of said detection mark from said predetermined position caused by the operation of said docking plate driving means; and
determining whether or not the state of fixation of said lid and said closed container is appropriate based on a result of detection of displacement of said docking plate and a result of detection of displacement of said detection mark.
